(19) United States
(12) Patent Application Publication
(10) Pub. No.: US 2024/0096640 A1
(43) Pub. Date: Mar. 21, 2024

(54) High Aspect Ratio Contact (HARC) Etch

(71) Applicant: Tokyo Election Limited, Tokyo (JP)

(72) Inventors: Pingshan Luan, Albany, NY (US); Matthew Ocana, Albany, NY (US); Andrew Metz, Albany, NY (US)

(73) Assignee: Tokyo Electron Limited, Tokyo (JP)

(21) Appl. No.: 17/948,768

(22) Filed: Sep. 20, 2022

(51) Int. Cl. H01L 21/311; H01J 37/32

(52) U.S. Cl. CPC H01L 21/31116; H01J 37/3244; H01L 21/31144; H01J 2237/3345; H01J 2237/3346

(57) ABSTRACT

A method of processing a substrate that includes: flowing nitrogen-containing (N-containing) gas, dioxygen (O₂), a noble gas, and a fluorocarbon into the plasma processing chamber, the plasma processing chamber configured to hold a substrate including a dielectric layer as etch target and a patterned hardmask over the target layer; while flowing the gases, generating a fluorine-rich and nitrogen-deficient plasma in the plasma processing chamber, fluorine-rich and nitrogen-deficient plasma being made of more number of fluorine species than nitrogen species; and forming a high aspect ratio feature by exposing the substrate to the fluorine-rich and nitrogen-deficient plasma to etch a recess in the dielectric layer.

### TECHNICAL FIELD

The present invention relates generally to methods of processing a substrate, and, in particular embodiments, to high aspect ratio contact (HARC) etch.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the processing steps used to form the constituent structures of semiconductor devices are performed using plasma processes.

The semiconductor industry has repeatedly reduced the minimum feature sizes in semiconductor devices to a few nanometers to increase the packing density of components. Accordingly, the semiconductor industry increasingly demands plasma processing technology to provide processes for patterning features with accuracy, precision, and profile control, often at atomic scale dimensions. Meeting this challenge along with the uniformity and repeatability needed for high volume IC manufacturing requires further innovations of plasma processing technology.

### SUMMARY

In accordance with an embodiment of the present invention, a method of processing a substrate that includes: flowing nitrogen-containing (N-containing) gas, dioxygen (O₂), a noble gas, and a fluorocarbon into the plasma processing chamber, the plasma processing chamber configured to hold a substrate including a dielectric layer as etch target and a patterned hardmask over the target layer; while flowing the gases, generating a fluorine-rich and nitrogen-deficient plasma in the plasma processing chamber, fluorine-rich and nitrogen-deficient plasma being made of more number of fluorine species than nitrogen species; and forming a high aspect ratio feature by exposing the substrate to the fluorine-rich and nitrogen-deficient plasma to etch a recess in the dielectric layer.

In accordance with an embodiment of the present invention, a method of processing a substrate that includes: selectively and anisotropically etching a dielectric layer to form a high aspect ratio (HAR) feature into the dielectric layer, where the etching is performed by exposing the substrate to a plasma generated from a gas mixture including a N-containing gas, O₂, Ar, and a unsaturated fluorocarbon and a saturated fluorocarbon, and where an aspect ratio of the HAR feature after the etching is at least 50:1.

In accordance with an embodiment of the present invention, a method of processing a substrate, the method including: loading the substrate in a plasma processing chamber, the substrate including a target dielectric layer and a patterned hardmask; flowing O₂, a noble gas, and a fluorocarbon into the plasma processing chamber; while flowing the gases, generating a plasma in the plasma processing chamber; while flowing the gases, exposing the substrate to the plasma to etch a recess in the dielectric layer; and while exposing the substrate to the plasma and before the recess reaches a half of a thickness of the dielectric layer, flowing a N-containing gas into the plasma processing chamber.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross sectional views of a material stack (150) on a Si wafer during an example process of semiconductor fabrication comprising a plasma etch process to form a high aspect ratio (HAR) feature on the material stack in accordance with various embodiments, wherein FIG. 1A illustrates an incoming wafer comprising a patterned hardmask layer (120), a target etch layer (110), and a bottom substrate (100), FIG. 1B illustrates the material stack (150) during the formation of the HAR feature by the plasma etch process, and

FIG. 1C illustrates the material stack (150) after completing the plasma etch process;

FIG. 2 illustrates top views of resulting structures of an example opening on a bottom substrate (100), where an ideal structure and a distorted and twisted structure are overlaid for comparison;

FIGS. 3A and 3B illustrate top views of the dimple structure on the bottom substrate (100) in FIG. 1 after a plasma etch processes, wherein FIG. 3A illustrates the bottom substrate (100) with distorted and uneven openings, and FIG. 3B illustrates the bottom substrate (100) with a uniform size and shape of opening with a minimal reduction in critical dimension (CD) in accordance with various embodiments;

FIG. 4 illustrates a scanning electron microscopic (SEM) image of an example Si bottom dimple after a plasma etch process with a distorted and twisted structure;

FIG. 5 illustrates a scanning electron microscopic (SEM) image of an example Si bottom dimple after a plasma etch process with a less distorted and twisted structure in accordance with various embodiments; and

FIGS. 6A-6C illustrate process flow diagrams of methods of semiconductor fabrication comprising a plasma etch process to form HAR features in accordance with various embodiments, wherein FIG. 6A illustrates an embodiment, FIG. 6B illustrates an alternate embodiment, and FIG. 6C illustrates yet another embodiment.

### DETAILED DESCRIPTION OF ILLUSTRATIVE EMBODIMENTS

This application relates to fabrication of semiconductor devices, for example, integrated circuits comprising semiconductor devices, and more particularly to high capacity three-dimensional (3D) memory devices, such as a 3D-NAND (or vertical-NAND), 3D-NOR, or dynamic random access memory (DRAM) device. The fabrication of such devices may generally require forming conformal, high aspect ratio (HAR) features (e.g., a contact hole) of a circuit element. Features with aspect ratio (ratio of height of the feature to the width of the feature) higher than 50:1 are generally considered to be high aspect ratio features, and in some cases fabricating a higher aspect ratio such as 100:1 may be desired for advanced 3D semiconductor devices. However, conventional HAR etch methods may usually comprise tens and sometimes hundreds of processing steps, for example employed as a cyclic process, which thereby complicates the process optimization and lowers etch throughput. Furthermore, conventional HAR etch methods may often suffer severe distortion and twisting in the final structures. Accordingly, the issues of low wafer throughput, poor uniformity, and missing contact remains challenging for HAR etch processes. A simple yet effective HAR process may therefore be desired. Embodiments of the present application disclose methods of fabricating HAR features by a plasma etch process based on a fluorocarbon assisted by nitrogen species. HAR features with aspect ratios, higher than 50:1, e.g., between 50:1 and 200:1 may be fabricated using embodiments discussed in this application.

The methods of plasma etch described in this disclosure may overcome various challenges posed for plasma etching processes for HAR features. In various embodiments, the plasma etch process may advantageously achieve a high AR equal to or higher than 100:1 with a good selectivity to a hardmask. Further, the methods improve the etch uniformity by reducing distortion and twisting of the etched features. This plasma etch process according to the methods may also be performed in a single step rather than a cyclic etch process that requires multiple steps.

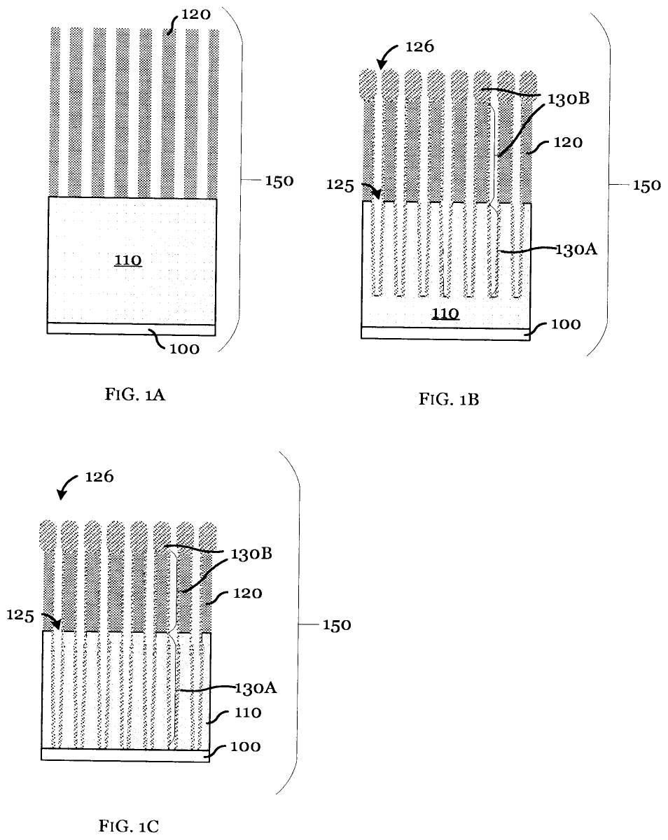

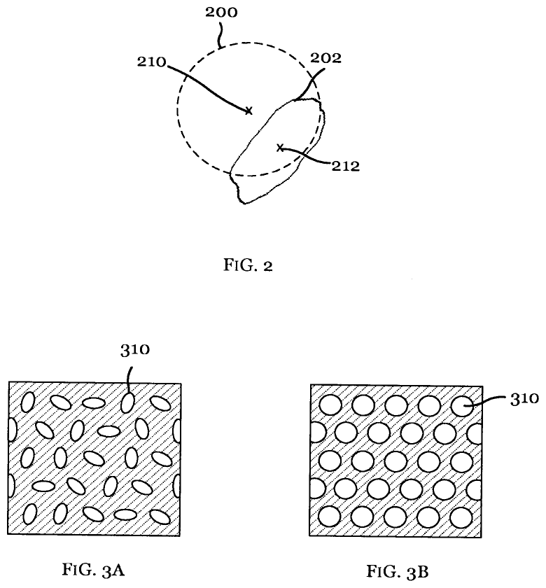

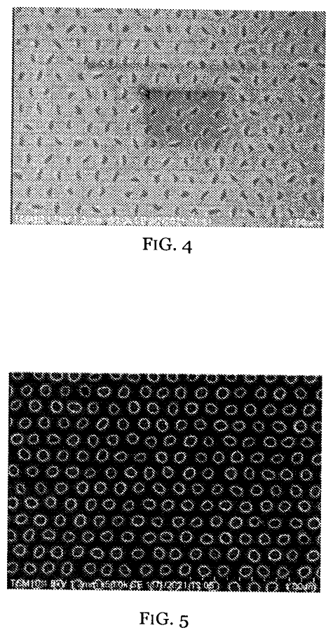

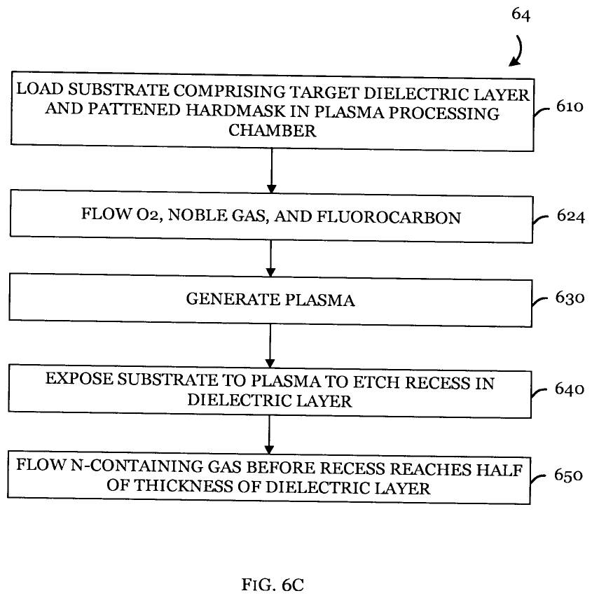

In the following, an exemplary plasma etch process to form a desired high aspect ratio (HAR) feature will be discussed with FIGS. 1A-1C in accordance with various embodiments. Next, the issue of distortion and twisting in a typical HAR feature formed by a conventional method is described referring to FIG. 2. The improvement of the HAR etch processes will be described referring to FIGS. 3A-3B, 4 and 5. Example process flow diagrams are then illustrated in FIG. 6A-6C. All figures are drawn for illustration purpose only and not to scale.

FIGS. 1A-1C illustrate cross sectional views of a material stack 150 during an example process of semiconductor fabrication comprising a plasma etch process to form a high aspect ratio (HAR) feature in accordance with various embodiments.

FIG. 1A illustrates a cross sectional view of an incoming material stack 150 comprising a patterned hardmask layer 120, a target etch layer 110, and a bottom substrate 100.

In one or more embodiments, the bottom substrate 100 may be a silicon wafer, or a silicon-on-insulator (SOI) wafer. In certain embodiments, the substrate may comprise a silicon germanium wafer, silicon carbide wafer, gallium arsenide wafer, gallium nitride wafer and other compound semiconductors. In other embodiments, the substrate comprises heterogeneous layers such as silicon germanium on silicon, gallium nitride on silicon, silicon carbon on silicon, as well layers of silicon on a silicon or SOI substrate.

In various embodiments, the material stack 150 is a part of, or include, a semiconductor device, and may have undergone a number of steps of processing following, for example, a conventional process. For example, the semiconductor structure may comprise a material stack 150 in which various device regions are formed. At this stage, the bottom substrate 100 may include isolation regions such as shallow trench isolation (STI) regions as well as other regions formed therein.

The target etch layer 110 may be formed over the bottom substrate 100. In various embodiments, the material layer 110 is a target layer that is to be patterned into one or more high aspect ratio (HAR) features. In certain embodiments, the HAR feature being etched into the material layer 110 may be a contact hole, slit, or other suitable structures comprising a recess. In one embodiment, the material layer 110 may be a silicon oxide (SiO₂) layer. The material layer 110 may be deposited using an appropriate technique such as vapor deposition including chemical vapor deposition (CVD), physical vapor deposition (PVD), atomic layer deposition (ALD), as well as other plasma processes such as plasma enhanced CVD (PECVD) and other processes. In one embodiment, the material layer 110 has a thickness between 1 μm and 10 μm.

Although not illustrated in FIG. 1A, the target etch layer 110 may be a layer stack comprising more than one material. In certain embodiments, the material layer 110 may comprise stacked films of alternating materials, such as an oxide-nitride-oxide-nitride (ONON) alternating stack or an oxide-polysilicon-oxide-polysilicon (OPOP) stack. Such stacked films may be particularly useful for fabricating 3D semiconductor structures such as 3D VNAND memory cells.

Still referring to FIG. 1A, the patterned hardmask layer 120 is formed over the material layer 110. In various embodiments, the patterned hardmask layer 120 may comprise amorphous carbon layer (ACL), or silicon (Si) in amorphous/polycrystalline state, or metallic carbides and silicides such as WC and WSi. The patterned hardmask layer 120 may be formed by first depositing a hardmask layer using, for example, an appropriate spin-coating technique or a vapor deposition technique such as chemical vapor deposition (CVD), physical vapor deposition (PVD), atomic layer deposition (ALD), as well as other plasma processes such as plasma enhanced CVD (PECVD) and other processes. The deposited hardmask layer may then be patterned using a lithography process and an anisotropic etch process. The relative thicknesses of the patterned hardmask layer 120 and the material layer 110 may have any suitable relationship. For example, the patterned hardmask layer 120 may be thicker than the material layer 110, thinner than the material layer 110, or the same thickness as the material layer 110. In certain embodiments, the patterned hardmask layer 120 has a thickness between 0.2 μm and 4 μm. In one embodiment, the patterned hardmask layer 120 comprises amorphous carbon layer (ACL) and has a thickness of 2.5 μm and a critical dimension (CD) of 75 nm, although in other embodiments, the thickness and the CD of the patterned hardmask layer 120 may have any suitable values depending on the material composition and target aspect ratio, respectively.

The patterned hardmask layer 120 and/or the target layer 110 may be collectively considered as a part of the bottom substrate 100. Further, although not specifically illustrated in FIG. 1A, the material stack 150 may also comprise other layers. For example, for the purpose of patterning the hardmask layer, a tri-layer structure comprising a photoresist layer, SiON layer, and optical planarization layer (OPL) may be present.

FIG. 1B illustrates a cross sectional view of the substrate during the formation of the HAR feature by the plasma etch process.

Fabricating the HAR feature in the material layer 110 may be performed by a plasma etch process using a combination of gases in accordance with various embodiments. The methods may particularly be characterized by the use of a fluorocarbon as a primary etch gas and an additive gas comprising nitrogen.

In various embodiments, the additive gas may comprise a nitrogen-containing (N-containing) gas such as dinitrogen (N₂), ammonia (NH₃), and various nitrogen oxides (e.g., NOₓ, with x=1, 2, 3; N₂O₅). The inventors of this application identified that even a small addition of the N-containing gas may advantageously reduce distortion and twisting of the resulting HAR feature without sacrificing the etch selectivity to the hardmask. As further described below, the process gas may be selected to generate a fluorine-rich and nitrogen-deficient plasma for the methods. In certain embodiments, the additive gas may comprise more than one N-containing gas. The reduction in distortion and twisting by the use of the N-containing gas will further be described below referring to FIGS. 2A-2B and 3-5.

In various embodiments, the fluorocarbon may be an unsaturated fluorocarbon such as hexafluorobutadiene (C₄F₆), hexafluoro-2-butyne (C₄F₆), hexafluorocyclobutene (C₄F₆), or octafluorocyclobutane (C₄F₈), or it may be a saturated fluorocarbon such as octafluoropropane (C₃F₈), perfluorobutane (C₄F₁₀), or perflenapent (C₅F₁₂), but other fluorocarbon may also be used. In this disclosure, an unsaturated fluorocarbon refers to any compound comprising carbon and fluorine with at least one carbon-carbon double bond (C═C bond), triple bond (CC bond), or ring-structure, and a saturated fluorocarbon refers to any compound comprising carbon and fluorine without any C═C bond, CC bond, or ring-structures. In one or more embodiments, more than one fluorocarbon may be used. For example, a gas mixture of C₄F₆ and C₃F₈ may be used. The addition of a saturated fluorocarbon to an unsaturated fluorocarbon may advantageously provide an improved sidewall passivation in HAR recesses formed in the target layer 110, while preventing clogging at the openings of the patterned hardmask layer 120.

In further embodiments, other gases such as a noble gas and/or a balancing agent may also be added. For example, in certain embodiments, argon (Ar) and dioxygen (O₂) may be included as the noble gas and the balancing agent, respectively. In alternate embodiments, the combination of gases may further comprise a third fluorocarbon. In one embodiment, the third fluorocarbon may be octafluoro-2-butene (C₄F₈), hexafluoropropylene (C₃F₆), carbon tetrafluoride (CF₄), fluoroform (CHF₃), difluoromethane (CH₂F₂), or fluoromethane (CH₃F).

Further improvement of the plasma etch process may be achieved by adding a second noble gas in accordance with various embodiments. In certain embodiments, the first noble gas is Ar and the second noble gas is Kr or He, resulting in improved etch selectivity and critical dimension uniformity (CDU). In certain embodiments, the plasma etch process may use a combination of gases comprising C₄F₆, C₃F₈, Ar, Kr, N₂ and O₂.

In FIG. 1B, the high aspect ratio (HAR) feature is being formed as recesses 125 in the material layer 110 by the plasma etch process. Generally, the plasma of a plasma etch process for HAR features offers two important species: (i) etchants for removing the target material (e.g., silicon oxide) and (ii) polymerizing radicals to form a polymeric deposition (e.g., sidewall deposition 130A and top deposition 130B), which may be used for sidewall passivation. In various embodiments, gas selection and process parameters may be determined to obtain a desired balance between the two.

As illustrated in FIG. 1B, by the plasma etch process, the recesses 125 may be formed straight and uniformly across the bottom substrate 100 with little to some degree of bowing. Bowing refers to the deviation of a perfectly straight recess from a purely anisotropic profile to a recess having outward curvature. Bowing may generally occur near the top of sidewalls of the etch target (e.g., the material layer 110), and may be caused by the bending of incident ion trajectories of ions used during the plasma etching process. Bowing may be minimized by the sidewall passivation in the recess 125. Such passivation may be achieved by sidewall deposition 130A of polymerizing radicals extending to the walls of the recesses 125.

At the same time, as illustrated in FIG. 1B, such a deposition of polymerizing radicals may also be formed as the top deposition 130B on the hardmask concentrated near openings 126 of the patterned hardmask layer 120. The top deposition 130B, if in excess, may be detrimental to the etch performance by causing clogging of the openings 126. In other words, a good balance between the sidewall deposition 130A and the top deposition 130B may need to be realized for the effective etch performance, which may be enabled by various embodiments.

In certain embodiments, the addition of the balancing agent such as dioxygen (O₂) may be beneficial in this aspect of controlling the amount of deposition. For example, dissociated oxygen species may help controlling the amount of the top deposition 130B, particularly near the openings 126. As a result, clogging may be prevented while the etchants and sidewall passivation species may reach into the recesses 125.

Also in the example of FIG. 1B, a sufficient overall etch rate with less processing steps enables the recesses 125 to form a high aspect ratio structure in a short process time compared to conventional HAR etch methods. Simultaneously, due to the co-optimization of gas flow rates and ratios only a small fraction of the hardmask may be consumed during the etch process, a good selectivity to the hardmask can be achieved. In some embodiments, the material layer 110 comprises silicon oxide and the etch selectivity of the silicon oxide may be at least four times greater than that of the hardmask.

FIG. 1C illustrates a cross sectional view of the material stack 150 after completing the plasma etch process.

Continuing the plasma etch process, the recesses 125 illustrated in FIG. 1B may be extended further by etching through the entire thickness of the target layer 110 and reach/land to the top surface of the bottom substrate 100 as illustrated in FIG. 1C. The plasma etch process in accordance with various embodiments may provide a good selectivity to silicon (Si) in addition to the target material 110. Accordingly, the plasma etch may be selective to the bottom substrate 100 and the formation of the recesses 125 may advantageously stop at the top surface of the bottom substrate 100. In certain embodiments, the polymer deposition on the exposed surface of the bottom substrate 100 may advantageously function as an etch stop layer, and such polymer deposition may be improved by species generated from the fluorocarbon.

In various embodiments, a RF pulsing at a kHz range may be used to power the plasma. Using the RF pulsing may help generating high energetic ions (>keV) in the plasma for the plasma etch process, while reducing a charging effect. The charging effect during a process is a phenomenon where electrons build charge on insulating materials (e.g., silicon oxide of the materials layer 110) creating a local electric field that may steer charged ions to the sidewalls and cause a non-vertical etching. Therefore, fine tuning the power conditions of the plasma etch process may also be important to minimize the widening of critical dimension (CD) and profile distortion of the high aspect ratio (HAR) feature. In certain embodiments, a kHz modulated dual frequency RF generator is used to power the plasma, with typical pulsing duty ratio between 20% and 90%. In one embodiment, a bias power of 40 MHz at 2 kW, and 400 kHz at 18 kW may be pulsed with a frequency of 5 kHz and a duty ratio of 50%.

In certain embodiments, where C₄F₆ and C₃F₈ are included as the fluorocarbon in the plasma etch process, the C₃F₈:C₄F₆ ratio may be kept within the range of 5:1 to 0.2:1.

In certain embodiments, where argon (Ar) and krypton (Kr) are included as the noble gases in the plasma etch process, the Kr gas may or may not be required for the etch process. In one embodiment, the Kr flow rate may be 250 sccm at a pressure between 10 mTorr to 30 mTorr. In one embodiment, the flow rate ratio Kr:Ar may be kept within the range of 0.1:1 to 5:1, for example, between 0.5:1 to 0.95:1 in one embodiment.

In various embodiments, the flow rate of the N-containing gas may be between 5% and 25% of a flow rate of the fluorocarbon. In certain embodiments, the flow rate of the N-containing gas is between 1% and 10% of the total gas flow. In one embodiment, the flow rate of the N-containing gas may be about 30 sccm. In one or more embodiments, where the N-containing gas is dinitrogen (N₂), the plasma etch process may be performed at gas flow rates of 90-100 sccm for C₄F₆, 65-75 sccm for C₃F₈, 60-70 sccm for O₂, 5-90 sccm for N₂, 340-360 sccm for Ar, and 260-290 sccm for Kr, at a temperature of 10-30° C., and at a pressure of 10-30 mTorr, using a dual-frequency capacitively coupled plasma (CCP) chamber with pulsing capabilities at a high frequency (HF) power of 500-6000 W, at a low frequency (LF) power at 5000-25000 W, at a pulsing frequency of 1-10 kHz, and at a pulsing duty ratio of 20-90%. With the example conditions above, the HAR feature with a high critical dimension uniformity (CDU) and a good sidewall passivation may be obtained (e.g., FIGS. 1B and 1C). Various process parameters and processing systems for the methods may be selected such that the plasma etching conditions are suitable for fabricating a HAR feature.

For plasma etching a dielectric layer with a fluorine-rich and nitrogen-deficient plasma as discussed in various embodiments, a capacitively coupled plasma (CCP) may be advantageous over an inductively coupled plasma (ICP) so as to achieve better anisotropic etching and improved etch profile with a controllable range of distortion while maintaining good etch selectivity.

In certain embodiments, the plasma etch process may be advantageously performed as a single step process with a process time of 60 min or less to form a high aspect ratio (HAR) feature with an aspect ratio of 100:1 or higher. In one embodiment, after 30-50 min of a continuous etching process, the plasma etch process may drill through a layer of 5-8 μm silicon oxide (SiO₂) with 20-30% over etch (OE) by sacrificing 1-2 μm of amorphous carbon layer (ACL) hardmask, which yields a SiO₂-to-ACL selectivity between 3:1 to 5:1. While a continuous process flow for the plasma etch process may be advantageous, other embodiments where the methods are applied as a part of a cyclic or multi-step process may also be possible.

In various embodiments, process parameters may be selected to optimize the characteristics of the high aspect ratio (HAR) feature considering various factors comprising controlled level of deposition, selectivity to the hardmask, sidewall passivation in the HAR feature, and good critical dimension uniformity (CDU) among others. In particular, the methods may advantageously reduce distortion and twisting of the resulting HAR feature through the effect of adding the N-containing gas.

FIG. 2 illustrates top views of resulting structures of an example opening, where an ideal structure and a distorted and twisted structure are overlaid for comparison;

FIGS. 3A and 3B illustrate top views of a substrate after a plasma etch process with different resulting structures.

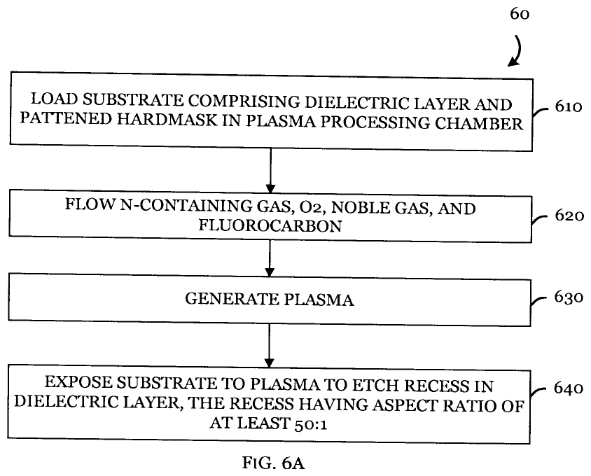

FIG. 4 illustrates a scanning electron microscopic (SEM) image of an example Si dimple after a plasma etch process with a distorted and twisted structure.

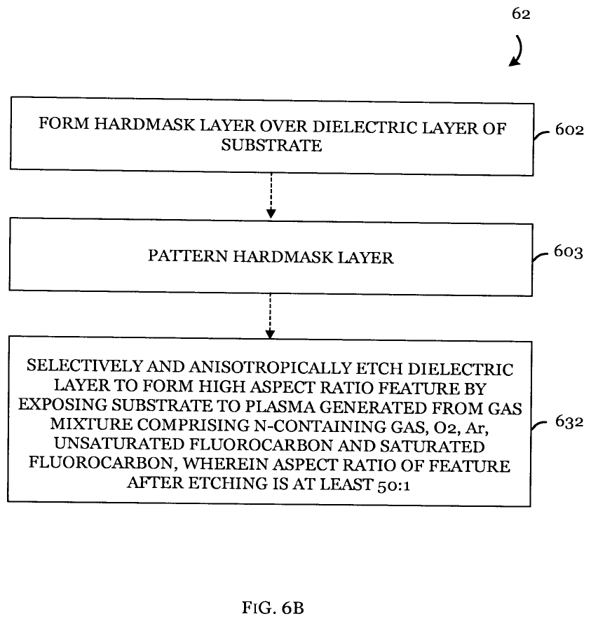

FIG. 5 illustrates a scanning electron microscopic (SEM) image of an example Si dimple after a plasma etch process with a less distorted and twisted structure in accordance with various embodiments.

Characteristics, such as distortion, twisting, CD and pattern defects of the HAR feature, may be measured using optical techniques such as scatterometry, scanning electron microscope (SEM), transmission electron microscope (TEM), high-resolution TEM (HR-TEM), scanning probe microscope (SPM), atomic force microscope (AFM), scanning tunneling microscope (STM), or other suitable devices.

As illustrated in FIG. 2, an ideal opening 200 should hold the original shape of the hardmask, such as circular, with the same center position 210 in the horizontal plane. In practice, however, an etch process often result in some deformations of the opening as a result of the non-ideality of etch process. Distortion and twisting are two major issues of deviation from the target features. First, in this disclosure, distortion refers to a deformation of a feature shape at the bottom of the recess. Due to distortion, the actual opening 202 after the etch process may have an elliptic shape or similar, as opposed to the circular shape of the ideal opening 200. Distortion may be quantitatively defined as the ratio of the minimal Feret diameter to the maximum Feret diameter of the actual opening 202. Accordingly, distortion may be presented as a value between 0 and 1, where 1 represent the ideal circular shape. Twisting, on the other hand, refers to a deviation of the central point of an opening. The position of the actual opening 202, as illustrated in FIG. 2, may be shifted as a result of the etch process. This shift may be represented by the deviation of an actual center 212 from the ideal center 210. In various embodiments, the addition of the N-containing gas in the process gas may reduce both of these two issues and thereby improve the fidelity of an etch process for high aspect ratio (HAR) feature.

In FIG. 3A, openings 310 have distorted shapes as a result of the plasma etch process. This may occur when the etch process is performed with no N-containing gas. The inventors of this application experimentally confirmed the issue of distortion as illustrated in the SEM image of FIG. 4, where the substrate was processed by a conventional multiple-step etch process using C₄F₆, C₄F₈, O₂, Ar, and Kr without N₂. The hardmask layer 120 and target etch layer 110 were removed prior to imaging to obtain the SEM image of FIG. 4.

In contrast, when an adequate level of the N-containing gas is flowed during the plasma etch process, the shape of the openings 310 may be substantially improved. As illustrated in FIG. 3B, the openings 310 may have ideal circular shapes without significant twisting. The inventors of this application experimentally confirmed such an improvement of the etch process as illustrated in the SEM image of FIG. 5, where the substrate was processed by the etch process, in accordance with one embodiment, using C₄F₆, C₄F₈, O₂, Ar, Kr, and N₂.

In various embodiments, the flow rate of N₂ may affect the distortion and the etch selectivity. Table 1 summarizes representative experimental results for the plasma etch process using gas flow rates of 95 sccm for C₄F₆, 70 sccm for C₃F₈, 62 sccm for O₂, 0-120 sccm for N₂, 350 sccm for Ar, and 275 sccm for Kr, at a temperature of 20° C. for 40 min, and at a pressure of 20 mTorr. The flow rate of N₂ was changed from 0 sccm to 120 sccm with increments of 30 sccm. By flowing 30 sccm or 60 sccm, the distortion was improved (0.7 to 0.86) while maintaining a good etch selectivity of silicon oxide to ACL hardmask (4:1 or greater). Increasing the flow rate of N₂ beyond 60 sccm led to more distortion and decrease in the etch selectivity, indicating an excessive amount of the N-containing gas may be detrimental to the etch performance. As demonstrated in Table 1 below, the inventors of this application have determined an critical range for the flow rate ratio between the nitrogen containing gas and the fluorocarbon over which the distortion improvement and the etch selectivity are maximized. In particular, as will be described in more detail, a fluorine-rich and nitrogen-deficient plasma is used for etching a dielectric layer. The fluorine-rich and nitrogen-deficient plasma has more number of fluorine species including radicals and ions relative to the number of oxygen species or the number of nitrogen species.

For example, an optimal flow rate of the additive gas (e.g., N containing gas such as N₂) may depend on the total flow rate and/or the flow rate of the primary etch gas (e.g., fluorocarbons). While not wishing to be limited by any theory, a flow rate ratio of the N-containing gas (e.g., N₂) to the fluorocarbon may be one of the key variables for optimizing the effect of the N-containing gas, for example, to minimize distortion. Accordingly, in certain embodiments, the flow rate of N₂ may be adjusted to be between 5% and 25% of a flow rate of the fluorocarbon. In one embodiment, to control the variation in the distortion, the flow rate of N₂ may be maintained between 1% and 10% of the total gas flow rate.

TABLE 1
Effect of N₂ flow rate

| N₂ flow rate [sccm] | Distortion [−] | Etch selectivity |
|---|---|---|
| 0 | 0.700 | 4.46 |
| 30 | 0.856 | 4.48 |
| 60 | 0.859 | 4.14 |
| 90 | 0.784 | 3.97 |
| 120 | 0.600 | 3.90 |

Furthermore, the timing of starting the flow rate of N₂ is also shown to influence distortion through experiments. Table 2 summarizes four representative data with varying the timing of flowing N₂. The primary experimental conditions were identical to those presented for Table 1 except the flowing of N₂. N₂ was flowed at 30 sccm when the etching is complete at different levels: 0%, 60%, 80%, and 90%. The results show that it is desirable to start flowing N₂ at the beginning of the etch process to improve distortion.

TABLE 2
Effect of timing of N₂ flow

| Timing of N₂ flow | Distortion [−] |
|---|---|
| At 0% etch | 0.856 |
| At 60% etch | 0.600 |
| At 80% etch | 0.538 |
| At 90% etch | 0.611 |

In various embodiments, the N-containing gas may be flowed continuously at a fixed flow rate as described above so far. In other embodiments, the flow rate of the N-containing gas may be increased or decreased during the plasma etch process. In yet alternate embodiments, the N-containing gas may be flowed intermittently. In one or more embodiments, this intermittent flowing may be performed by pulsing the N-containing gas at a certain frequency, for example, between between 0.1 Hz and 10 Hz.

FIGS. 6A-6C illustrate process flow diagrams of methods of semiconductor fabrication comprising a plasma etch process to form HAR features in accordance with various embodiments. The process flow can be followed with the figures discussed above (e.g., FIGS. 1A-1C) and hence will not be described again.

In FIG. 6A, in accordance with an embodiment, a process flow 60 may start with loading a substrate comprising a dielectric etch target layer (e.g., SiO₂ layer) and a patterned ACL hardmask in a plasmas processing chamber (block 610, FIG. 1A). Next, a N-containing gas (e.g., N₂), O₂, a noble gas, and a fluorocarbon may be flowed into the plasma processing chamber (block 620). While flowing the gases, a plasma may be then generated in the plasma processing chamber (block 630). Subsequently, while flowing the gases, the substrate may be exposed to the plasma to etch a recess in the dielectric layer, where the recess being etched to have an aspect ratio of at least 50:1 (block 640, FIGS. 1B and 1C).

In FIG. 6B, in accordance with another embodiment, a process flow 62 may start with forming a hardmask layer over a dielectric layer of a substrate (block 602), followed by patterning the hardmask layer (block 603, FIG. 1A). Next, the process flow 62 may proceed to selectively and anisotropically etching the dielectric layer to form a high aspect ratio (HAR) feature (e.g., a plurality of circular holes) into the dielectric layer (block 632, FIGS. 1B and 1C). The etching of the dielectric layer may be performed by exposing the substrate to a plasma generated from a gas mixture comprising a N-containing gas (e.g., N₂), O₂, Ar, and an unsaturated fluorocarbon and a saturated fluorocarbon, and an aspect ratio of the HAR feature after the etching may be at least 50:1.

In FIG. 6C, in accordance with another embodiment, a process flow 64 may start with loading a substrate in a plasma processing chamber, where the substrate comprises a dielectric layer (e.g., SiO₂ layer) and a patterned ACL hardmask (block 610, FIG. 1A). Next, O₂, a noble gas, and a fluorocarbon may be flowed into the plasma processing chamber (block 624), and while flowing the gases, a plasma may be generated in the plasma processing chamber (block 630). Subsequently, while flowing the gases, the substrate may be exposed to the plasma to etch a recess in the dielectric layer (block 640, FIG. 1B), and while exposing the substrate to the plasma and before the recess reaches a half of a thickness of the dielectric layer, flowing a N-containing gas (e.g., N₂) in the plasma processing chamber (block 650, FIGS. 1B and 1C).

As described above, various embodiments may use a N-containing gas (e.g., N₂) in a plasma etch process for fabricating a high aspect ratio (HAR) feature, which may advantageously reduce distortion and twisting that are challenging to overcome with conventional HAR processes. The inventors of this application experimentally demonstrated that the addition of N₂ to the process gas introduces nitrogen species in the plasma. When 30 sccm N₂ was added to a process gas of 95 sccm for C₄F₆, 70 sccm for C₃F₈, 62 sccm for O₂, 30 sccm for N₂, 350 sccm for Ar, and 275 sccm for Kr, at a temperature of 20° C. for 40 min, and at a pressure of 20 mTorr, an optical emission spectroscopy (OES) analysis revealed new additional emission peaks attributed to N₂ secondary positive species (SPS) present in the plasma, while no significant change was found for other species such as CF, CF₂, Kr, Ar, and O species. In addition, the inclusion of nitrogen into the deposit was also experimentally evidenced. Polymeric depositions formed by the plasma etch process using N₂ as the additive gas (30 sccm and 120 sccm) were characterized experimentally by X-ray photoelectron spectroscopy (XPS). The XPS analysis confirmed the presence of C—N bonds in the polymeric depositions only from the N₂-added experiments, but not from the experiment with no N₂ addition. The surface elemental composition of nitrogen was in the range of 1% to 2%, which increased with the increase in N₂ flow rate.

Example embodiments of the invention are summarized here. Other embodiments can also be understood from the entirety of the specification as well as the claims filed herein.

Example 1. A method of processing a substrate that includes: flowing nitrogen-containing (N-containing) gas, dioxygen (O₂), a noble gas, and a fluorocarbon into the plasma processing chamber, the plasma processing chamber configured to hold a substrate including a dielectric layer as etch target and a patterned hardmask over the target layer; while flowing the gases, generating a fluorine-rich and nitrogen-deficient plasma in the plasma processing chamber, the fluorine-rich and nitrogen-deficient plasma being made of more number of fluorine species than nitrogen species; and forming a high aspect ratio feature by exposing the substrate to the fluorine-rich and nitrogen-deficient plasma to etch a recess in the dielectric layer.

Example 2. The method of example 1, further including flowing another noble gas different from the noble gas.

Example 3. The method of example 2, where the noble gas is Ar and the another noble gas is Kr or He.

Example 4. The method of one of examples 1 to 3, where the fluorocarbon includes C₄F₆, C₄F₈, CF₄, CHF₃, or CH₂F₂.

Example 5. The method of one of examples 1 to 4, where the N-containing gas includes dinitrogen (N₂), ammonia (NH₃), or nitrogen oxide.

Example 6. The method of one of examples 1 to 5, where a flow rate of the N-containing gas is between 5% and 25% of a flow rate of the fluorocarbon.

Example 7. The method of one of examples 1 to 6, where a flow rate of the N-containing gas is between 1% and 10% of a total gas flow.

Example 8. The method of one of examples 1 to 7, where the N-containing gas is flowed continuously while exposing the substrate to the plasma.

Example 9. The method of one of examples 1 to 7, where the N-containing gas is flowed intermittently while exposing the substrate to the plasma.

Example 10. The method of one of examples 1 to 9, further including powering the fluorine-rich and nitrogen-deficient plasma by capacitively coupling the fluorine-rich and nitrogen-deficient plasma to a power source.

Example 11. The method of one of examples 1 to 10, where the aspect ratio of the recess is at least 100:1.

Example 12. The method of one of examples 1 to 11, where an etch selectivity of the dielectric layer to the patterned hardmask is at least 3:1.

Example 13. The method of one of examples 1 to 12, where the patterned hardmask includes amorphous carbon layer (ACL), amorphous-silicon (a-Si) in polycrystalline-silicon (p-Si), metallic carbide, or metallic silicide.

Example 14. A method of processing a substrate that includes: selectively and anisotropically etching a dielectric layer to form a high aspect ratio (HAR) feature into the dielectric layer, where the etching is performed by exposing the substrate to a plasma generated from a gas mixture including a N-containing gas, O₂, Ar, a unsaturated fluorocarbon, and a saturated fluorocarbon, and where an aspect ratio of the HAR feature after the etching is at least 50:1.

Example 15. The method of example 14, where a concentration of the N-containing gas in the gas mixture is between 5% and 25% of a total concentration of the fluorocarbons.

Example 16. The method of one of examples 14 or 15, where the N-containing gas is N₂, the unsaturated fluorocarbon is C₄F₆, and the saturated fluorocarbon is C₃F₈.

Example 17. The method of one of examples 14 to 16, where the HAR feature includes a plurality of circular holes, one of the plurality of circular holes, after the etching, having a distorted circular shape at a bottom, and where a minimum diameter of the distorted circular shape is at least 80% of a maximum diameter of the distorted circular shape.

Example 18. A method of processing a substrate that includes: loading the substrate in a plasma processing chamber, the substrate including a target dielectric layer and a patterned hardmask; flowing O₂, a noble gas, and a fluorocarbon into the plasma processing chamber; while flowing the gases, generating a plasma in the plasma processing chamber; while flowing the gases, exposing the substrate to the plasma to etch a recess in the dielectric layer; and while exposing the substrate to the plasma and before the recess reaches a half of a thickness of the dielectric layer, flowing a N-containing gas into the plasma processing chamber.

Example 19. The method of example 18, where flowing the N-containing gas includes pulsing the N-containing gas at a frequency between 0.1 Hz and 10 Hz.

Example 20. The method of one of examples 18 or 19, where the recess having an aspect ratio of at least 50:1.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of processing a substrate, the method comprising:
flowing nitrogen-containing (N-containing) gas, dioxygen (O₂), a noble gas, and a fluorocarbon into the plasma processing chamber, the plasma processing chamber configured to hold a substrate comprising a dielectric layer as an etch target and a patterned hardmask over the dielectric layer;
while flowing the gases, generating a fluorine-rich and nitrogen-deficient plasma in the plasma processing chamber, the fluorine-rich and nitrogen-deficient plasma being made of more number of fluorine species than nitrogen species; and
forming a high aspect ratio feature by exposing the substrate to the fluorine-rich and nitrogen-deficient plasma to etch a recess in the dielectric layer.

2. The method of claim 1, further comprising flowing another noble gas different from the noble gas.

3. The method of claim 2, wherein the noble gas is Ar and the another noble gas is Kr or He.

4. The method of claim 1, wherein the fluorocarbon comprises C₄F₆, C₄F₈, CF₄, CHF₃, or CH₂F₂.

5. The method of claim 1, wherein the N-containing gas comprises dinitrogen (N₂), ammonia (NH₃), or nitrogen oxide.

6. The method of claim 1, wherein a flow rate of the N-containing gas is between 5% and 25% of a flow rate of the fluorocarbon.

7. The method of claim 1, wherein a flow rate of the N-containing gas is between 1% and 10% of a total gas flow rate.

8. The method of claim 1, wherein the N-containing gas is flowed continuously while exposing the substrate to the fluorine-rich and nitrogen-deficient plasma.

9. The method of claim 1, wherein the N-containing gas is flowed intermittently while exposing the substrate to the fluorine-rich and nitrogen-deficient plasma.

10. The method of claim 1, the method further comprising powering the fluorine-rich and nitrogen-deficient plasma by capacitively coupling the fluorine-rich and nitrogen-deficient plasma to a power source.

11. The method of claim 1, wherein the aspect ratio of the recess is at least 100:1.

12. The method of claim 1, wherein an etch selectivity of the dielectric layer to the patterned hardmask is at least 3:1.

13. The method of claim 1, wherein the patterned hardmask comprises amorphous carbon layer (ACL), amorphous-silicon (a-Si) in polycrystalline-silicon (p-Si), metallic carbide or metallic silicide.

14. A method of processing a substrate, the method comprising:
selectively and anisotropically etching a dielectric layer to form a high aspect ratio (HAR) feature into the dielectric layer;
wherein the etching is performed by exposing the substrate to a plasma generated from a gas mixture comprising a N-containing gas, O₂, Ar, an unsaturated fluorocarbon, and a saturated fluorocarbon; and
wherein an aspect ratio of the HAR feature after the etching is at least 50:1.

15. The method of claim 14, wherein a concentration of the N-containing gas in the gas mixture is between 5% and 25% of a total concentration of the fluorocarbons.

16. The method of claim 14, wherein the N-containing gas is N₂, the unsaturated fluorocarbon is C₄F₆, and the saturated fluorocarbon is C₃F₈.

17. The method of claim 14, wherein the HAR feature comprises a plurality of circular holes, one of the plurality of circular holes, after the etching, having a distorted circular shape at a bottom, and wherein a minimum diameter of the distorted circular shape is at least 80% of a maximum diameter of the distorted circular shape.

18. A method of processing a substrate, the method comprising:
loading the substrate in a plasma processing chamber, the substrate comprising a target dielectric layer and a patterned hardmask overlying the target dielectric layer;
flowing O₂, a noble gas, and a fluorocarbon into the plasma processing chamber;
while flowing the gases, generating a plasma in the plasma processing chamber;
while flowing the gases, exposing the substrate to the plasma to etch a recess in the target dielectric layer; and
while exposing the substrate to the plasma and before the recess reaches a half of a thickness of the target dielectric layer, flowing a N-containing gas into the plasma processing chamber.

19. The method of claim 18, wherein flowing the N-containing gas comprises pulsing the N-containing gas at a frequency between 0.1 Hz and 10 Hz.

20. The method of claim 18, wherein the recess having an aspect ratio of at least 50:1.
